(19) United States
(12) Patent Application Publication
(10) Pub. No.: US 2024/0387439 A1
(43) Pub. Date: Nov. 21, 2024

(54) DIRECT GANG BONDING METHODS AND STRUCTURES

(71) Applicant: Adeia Semiconductor Bonding Technologies Inc., San Jose, CA (US)

(72) Inventors: Belgacem Haba, Saratoga, CA (US); Laura Wills Mirkarimi, Sunol, CA (US); Javier A. DeLaCruz, San Jose, CA (US); Rajesh Katkar, Milpitas, CA (US); Cyprian Emeka Uzoh, San Jose, CA (US); Guilian Gao, San Jose, CA (US); Thomas Workman, San Jose, CA (US)

(21) Appl. No.: 18/784,724

(22) Filed: Jul. 25, 2024

Related U.S. Application Data
(62) Division of application No. 16/874,527, filed on May 14, 2020, now Pat. No. 12,080,672.
(60) Provisional application No. 62/906,608, filed on Sep. 26, 2019.

(51) Int. Cl. H01L 23/00; H01L 23/31

(52) U.S. Cl. CPC H01L 24/32; H01L 23/3107; H01L 24/27; H01L 24/29; H01L 24/83; H01L 2224/29187; H01L 2224/32145; H01L 2224/32225; H01L 2224/83005; H01L 2224/83896

(57) ABSTRACT

A bonded structure can comprise a first element and a second element. The first element has a first dielectric layer including a first bonding surface and at least one first side surface of the first element. The second element has a second dielectric layer including a second bonding surface and at least one second side surface of the second element. The second bonding surface of the second element is directly bonded to the first bonding surface of the first element without an adhesive.

### CROSS-REFERENCE TO RELATED APPLICATIONS

This application is a divisional of application Ser. No. 16/874,527, filed May 14, 2020, which claims priority to U.S. Provisional Patent Application No. 62/906,608, filed Sep. 26, 2019, the entire contents of which are incorporated by reference in their entirety and for all purposes.

### BACKGROUND

### Field of the Invention

The field relates to direct gang bonding methods and structures.

### Description of the Related Art

In various packaging arrangements, it can be advantageous to enable the use of multiple integrated device dies within a low-profile package. For example, three-dimensional (3D) integration techniques often utilize packages in which two or more integrated device dies are stacked on top of and electrically connected to one another. Conventional methods for die thinning and/or 3D integration may have limited product yield because stresses imparted to the dies during assembly may damage dies in the stack. Moreover, it can be challenging to stack dies which have different thicknesses and which have high pin counts and which may originate from different types of substrates and/or wafers. Accordingly, there remains a continuing need for improved systems and methods for stacking integrated device dies.

### BRIEF DESCRIPTION OF THE DRAWINGS

These aspects and others will be apparent from the following description of preferred embodiments and the accompanying drawing, which is meant to illustrate and not to limit the invention, wherein:

FIGS. 1A-1G are schematic side cross-sectional views of various stages of a direct bonding process, according to one embodiment.

FIG. 1E′ is another example of FIG. 1E according to one embodiment.

FIG. 1F′ is another example of FIG. 1F according to one embodiment.

FIGS. 2A-2E are schematic side cross-sectional views of various stages of a direct bonding process, according to another embodiment.

FIGS. 3A-3C illustrate various stages of a direct gang bonding process in which elements are directly bonded to one another without intervening adhesives.

FIGS. 4A-4D illustrate examples of bonded structures according to various embodiments.

FIG. 5A illustrates schematic side cross-sectional views of a bonded structure according to various embodiments.

FIGS. 5B-5D illustrate enlarged views of a portion of the bonded structure of FIG. 5A.

FIG. 6 is a schematic diagram of a system incorporating one or more bonded structures according to various embodiments.

### DETAILED DESCRIPTION

Some methods of stacking integrated device dies can mount multiple first dies to a tape structure and stack second dies onto the first dies that are disposed on the tape structure. However, the use of a tape structure to support the first dies may inadequately secure the first dies to the tape structure. Moreover, in some methods, the stacked dies can be overmolded or otherwise processed into a reconstituted wafer for subsequent processing. Overmolding or other steps in the reconstitution process may induce stresses on the integrated device dies, may be costly, and/or may utilize a thick layer of low coefficient of thermal expansion (CTE) material which may be difficult to manufacture. Accordingly, there remains a continuing need for improved stacking of elements such as integrated device dies.

Various embodiments disclosed herein relate to direct gang bonding methods and structures. For example, in various embodiments, a first plurality of elements can be simultaneously directly bonded to a second plurality of elements without intervening adhesives. Prior to and during direct bonding, adjacent elements on a carrier may be spaced apart by a gap that is not filled with a filling material. The lack of a filling material during direct bonding can reduce thermal stresses that may occur if a filling material were used between adjacent elements and can also simplify the deposition process. In various embodiments, a dielectric layer can be conformally deposited over upper and side surfaces of the elements. After bonding, outer side surfaces of the dielectric layers of two bonded elements may be laterally offset relative to one another.

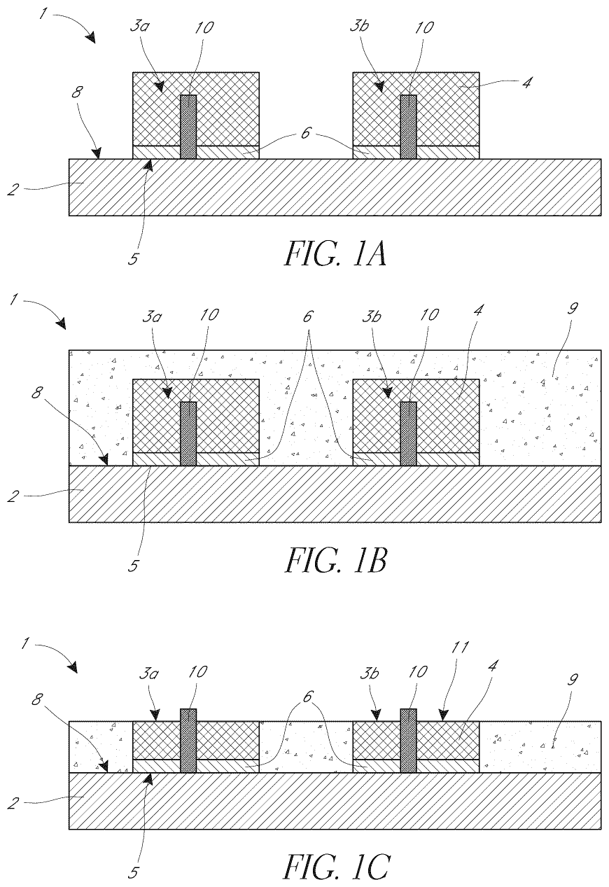

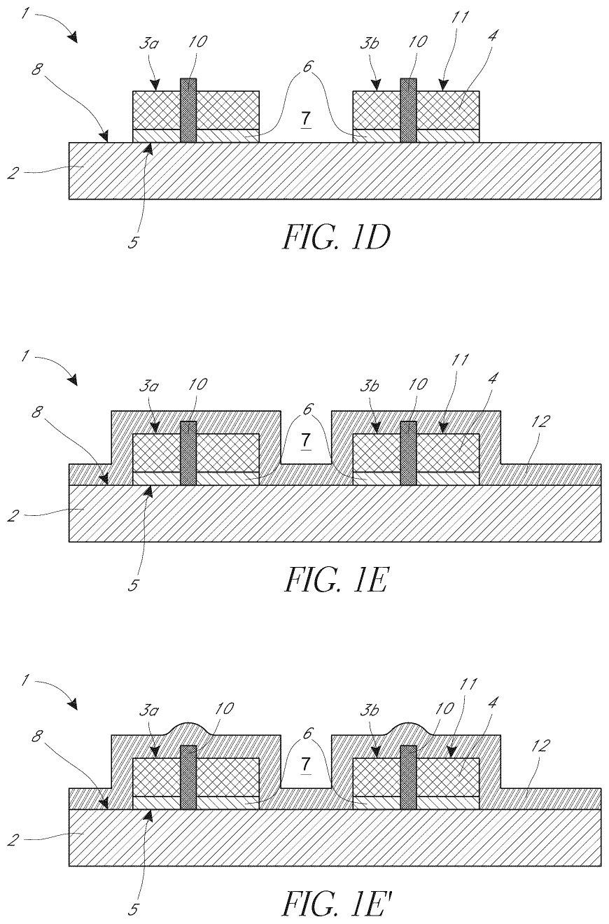

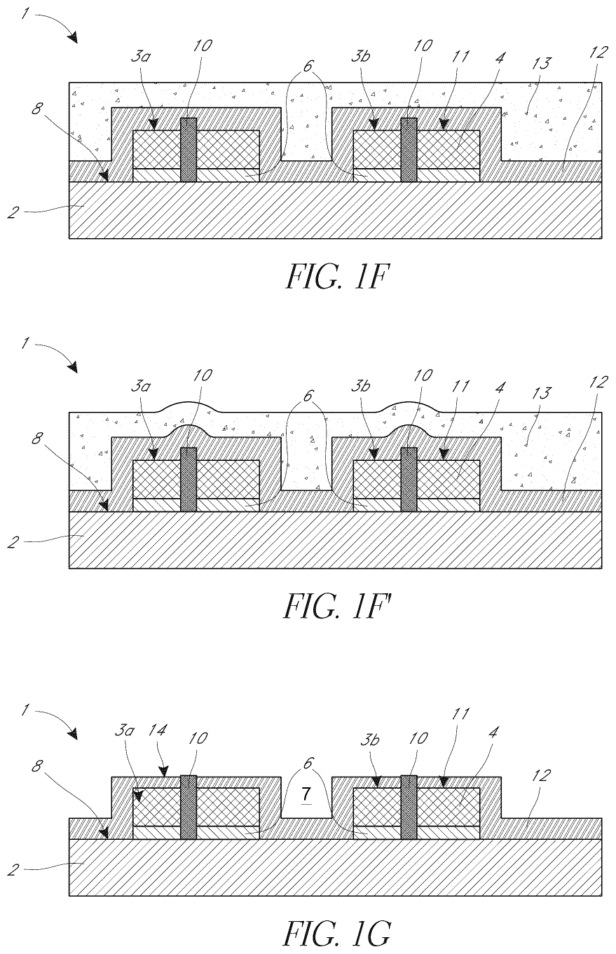

FIGS. 1A-1G are schematic side cross-sectional views of various stages of a method for preparing elements 3a, 3b for forming a bonded structure 1, according to one embodiment. In FIG. 1A, a first plurality of elements 3a, 3b can be mounted to an upper surface 8 of a carrier 2. In the illustrated embodiment, the elements 3a, 3b can be directly bonded to the upper surface 8 of the carrier 2 without an intervening adhesive. The carrier 2 can comprise for example, a substrate (e.g., a semiconductor substrate), an interposer, a wafer, a reconstituted wafer, or any other suitable type of carrier. In some embodiments, the carrier 2 can comprise a silicon substrate (e.g., part or all of a wafer), a glass substrate, or silicon on insulator (SOI) substrate or planar dielectric surface 8. The use of silicon, glass, or other semiconductor material for the carrier 2 can advantageously enable the upper surface 8 of the carrier 2 to be polished to a very low surface roughness so that the first elements 3a, 3b can be directly bonded to the carrier 2. In the illustrated embodiment, for example, the carrier 2 can comprise a silicon carrier with a dielectric surface, for example, an oxide layer formed on the upper surface 8. The dielectric surface or the oxide layer can be formed in any suitable manner, for example, by thermal oxidation, Plasma Enhanced Chemical Vapor Deposition (PECVD), chemical oxidation, sputtering, evaporation, atomic layer deposition (ALD), etc.

The elements 3a, 3b can comprise any suitable type of element, such as a semiconductor element. In various embodiments, the elements 3a, 3b can comprise integrated device dies (e.g., integrated circuit, dies, memory dies, microelectromechanical systems dies, sensor dies, etc.). As shown the elements 3a, 3b can include an active surface or region 6 that is patterned with active devices, such as electronic devices like transistors. One or a plurality of interconnects or vias 10 can extend through a portion of the elements 3a, 3b shown in FIG. 1A. In the step of FIG. 1A, the vias 10 can extend from a bottom surface 5 of the active region 6 into a bulk portion 4 (e.g., bulk silicon portion) of the elements 3a, 3b. The vias 10 can be connected to contact pads on the bottom surface 5 of the elements 3a, 3b that are directly bonded to corresponding contact or bond pads on the upper surface 8 of the carrier 2. The elements 3a, 3b may comprise the same type of element or different types of elements in various embodiments.

To accomplish the direct bonding, in some embodiments, the bonding surfaces of the elements 3a, 3b and the carrier 2 can be prepared for bonding. The elements 3a, 3b can be polished to a very high degree of smoothness (e.g., less than 20 nm surface roughness, less than 1 nm surface roughness, or more particularly, less than 0.5 nm roughness). In some embodiments, a bonding layer (not shown) (e.g., a dielectric such as silicon oxide) may be deposited on the active surfaces 6 of the elements 3a, 3b and polished to a very high degree of smoothness. Similarly, the bonding surface of the carrier 2 (e.g., the upper surface 8 of the carrier 2) may be polished to a very high degree of smoothness (e.g., less than 20 nm surface roughness, less than 1 nm surface roughness, or more particularly, less than 0.5 nm roughness). In some embodiments, the bonding surfaces may be fluorinated to improve bonding energy or strength between the bonding surface of the carrier 2 and the mating or bonding surfaces of elements 3a and 3b. The bonding surfaces may also include conductive features, such as conductive bond or contact pads, conductive traces or conductive dummy features. In some embodiments, the surfaces to be bonded may be terminated with a suitable species and activated prior to bonding. For example, in some embodiments, the surfaces to be bonded may be very lightly etched for activation and exposed to a nitrogen-containing solution and terminated with a nitrogen-containing species. As one example, the surfaces to be bonded may be exposed to an ammonia dip after a very slight etch, and/or a nitrogen-containing plasma (with or without a separate etch).

Once the surfaces are prepared, nonconductive field regions of the elements 3a, 3b can be brought into contact with corresponding nonconductive field regions of the carrier 2. The interaction of the activated surfaces can cause the nonconductive regions of the elements 3a, 3b to directly bond with the corresponding nonconductive regions of the carrier 2 without an intervening adhesive, without application of external pressure, without application of voltage, and about room temperature. In various embodiments, the bonding strength of the nonconductive regions can be covalent bonds that are greater than Van der Waals bonds. In various embodiments, the nonconductive regions are initially bonded at about room temperature. In some embodiments, covalent bonding can occur during a natural anneal at about room temperature or during a heated anneal. In some embodiments, the interconnects or vias 10 and/or the contact pads are flush or slightly recessed relative to the exterior surfaces of the elements 3a, 3b and the carrier 2. In other embodiments, one of the interconnects 10 and/or the contact pads may extend above the exterior surfaces of the elements 3a, 3b and the carrier 2. In still other embodiments, the interconnects 10 and/or the contact pads are recessed relative to the exterior surfaces (e.g., oxide field regions) of the elements 3a, 3b and the carrier 2. Depending on the depth and width of the conductive features 10, the recess may range between 1 to 40 nm. The bonded structure 1 can be annealed after the nonconductive regions are bonded to create contact and a direct bond between opposing conductive regions (e.g., between opposing contact pads) without an intervening adhesive. The bonded structure 1 can be annealed after the nonconductive regions are bonded to create contact and a direct bond between opposing conductive regions (e.g., between opposing contact pads) without an intervening adhesive. In various embodiments, the carrier 2 and elements 3a, 3b may be heated after bonding to strengthen the bonds between the nonconductive regions, between the conductive regions, and/or between opposing conductive and non-conductive regions, to cause the elements 3a, 3b to bond with the carrier 2. Additional details of the direct bonding processes may be found throughout U.S. Pat. Nos. 7,126,212; 8,153,505; 7,622,324; 7,602,070; 8,163,373; 8,389,378; 8,735,219; 9,953,941; and 10,204,893, and throughout U.S. Patent Publication No. US 2017/0200711, the contents of each of which are hereby incorporated by reference herein in their entirety and for all purposes.

Turning to FIG. 1B, a sacrificial filler material 9 can be provided over the elements 3a, 3b and the upper surface 8 of the carrier 2, and filling the space between the elements 3a, 3b. The sacrificial filler material 9 can comprise any suitable type of temporary or sacrificial material that can be removed by way of subsequent processing. For example, in various embodiments, the sacrificial material 9 can comprise a photoresist material, such as a hard baked photoresist, a spin on polymer coating, an adhesive film, polyimide, etc. In FIG. 1C, the partially-formed structure 1 can be thinned. For example, a portion of the sacrificial material 9 and a portion of the elements 3a, 3b can be selectively removed to thin the structure 1. For example, an upper surface of the sacrificial material 9 can be grinded, polished, dry etched with a plasma process, or wet etched with a chemical to expose upper sides of the elements 3a, 3b. In various embodiments, grinding and chemical mechanical polishing (CMP) can be used to remove the upper portion of the sacrificial filler material 9 and upper portions of the elements 3a, 3b. The portions of the upper sides of the elements 3a, 3b can also be removed to expose the interconnects or vias 10 at an exposed upper surface 11 of bulk portions 4 of the elements 3a, 3b. As illustrated in FIG. 1C, a portion of the interconnects 10 can protrude from a surface of the bulk portions 4. In some arrangements, the sacrificial filler material 9 may facilitate planarization of the exposed surfaces 11 of the elements 3a, 3b while reducing stresses on the corners of elements 3a, 3b.

In FIG. 1D, the sacrificial filler material 9 can be removed such that no filler material is disposed over or between the elements 3a, 3b. For example, the sacrificial filler material 9 can be removed by a wet or dry etching process, a plasma etching process, a stripping process, etc. In arrangements in which there is no sacrificial material, the upper corners or edges between the horizontal and vertical portions of element 3a and 3b may crack or chip off if gentle pressures are not utilized during the thinning and polishing of the backsides of element 3a and 3b. In FIG. 1D, the elements 3a, 3b can be separated by a gap 7. The gap 7 may not include a filling material, for example, the gap 7 may be filled with a gas (such as air) or may be under vacuum. Turning to FIG. 1E, a dielectric material comprising a dielectric layer 12 can be deposited over the elements 3a, 3b and over portions of the upper surface 8 of the carrier 2 disposed between adjacent elements 3a, 3b. In some embodiments, the dielectric layer 12 may comprise a conformal dielectric coating, as illustrated in FIG. 1E′. For example, a portion of the dielectric layer 12 above the protruded via 10 can be higher than area surrounding the portion. In some applications, the thickness of the dielectric layer 12 is smaller than the thickness of elements 3a or 3b. The dielectric layer 12 can serve as a protective material to protect the upper and side surfaces of the elements 3a, 3b. The dielectric layer 12 can also be selected to serve as a nonconductive bonding layer or region for subsequent direct bonding steps. The dielectric layer 12 can comprise any suitable type of dielectric material. For example, in various embodiments, the dielectric layer 12 can comprise silicon oxide, silicon nitride, silicon oxynitride, silicon carbide, or any other suitable dielectric. In some embodiments, the dielectric layer 12 may comprise multiple layers of different dielectric materials. At the edge of the die, the dielectric layer 12 can cover debris or cracks weakly bonded due to die singulation and which might negatively impact the bond. As shown the gap 7 can be disposed between portions of the dielectric layer 12 disposed on sidewalls of adjacent elements 3a, 3b.

A second sacrificial filler material 13 can be provided over the dielectric layer 12 including the gaps 7 in FIG. 1F. In some embodiments, the second sacrificial layer 13 may comprise a dielectric coating, as illustrated in FIG. 1F′. As with the sacrificial filler material 9, the second sacrificial filler material 13 can facilitate thinning of the partially-formed bonded structure 1. Turning to FIG. 1G, the partially-formed bonded structure 1 can be thinned. For example, an upper portion of the second sacrificial filler material 13 and upper portions of the dielectric layer 12 can be selectively removed, for example, by polishing, grinding, etc. In some embodiments, the second sacrificial material 13 can be then completely removed. As shown in FIG. 1G, only a portion of the dielectric layer 12 can be removed, so as to expose the vias 10 at an exposed upper portion 14 of the dielectric layer 12.

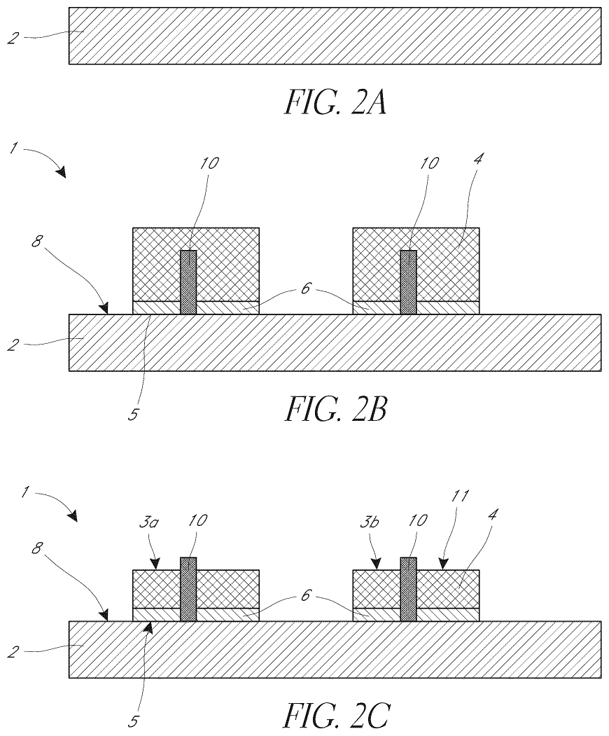

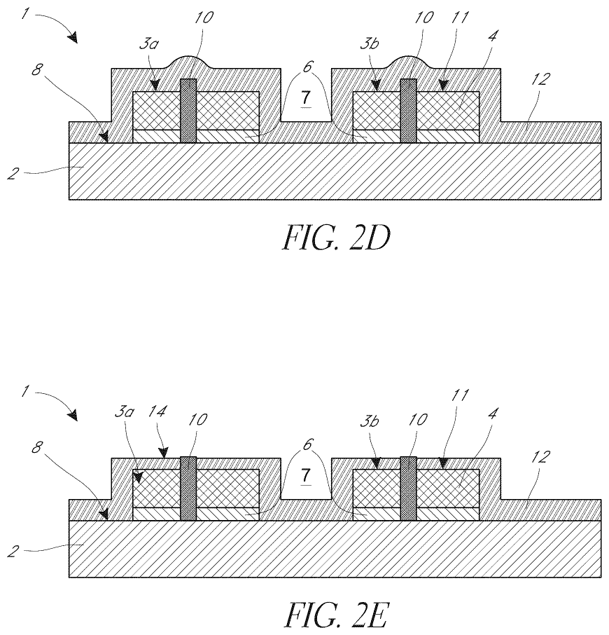

FIGS. 2A-2E are schematic side cross-sectional views of various stages of a method for forming a preliminary bonded structure 1, according to another embodiment. Unless otherwise noted, the components of FIGS. 2A-2E may be the same as or generally similar to like-numbered components of FIGS. 1A-1G. In FIG. 2A, a carrier 2 can be provided. As shown in FIG. 2B, as with FIG. 1A, elements 3a, 3b can be directly bonded to the carrier 2 without an intervening adhesive. Moving to FIG. 2C, the preliminary bonded structure 1 can be thinned, for example, upper surfaces of the elements 3a, 3b, for example the bulk portion 4, can be selectively removed (e.g., by grinding, polishing, dry etched with a plasma process, or wet etched with a chemical) without providing a sacrificial filler material over and between the elements 3a, 3b. Thus, in some embodiments, the elements 3a, 3b can be planarized to expose the vias 10 at exposed surface 11 without using a sacrificial filler material. As illustrated in FIG. 2C, a portion of the vias 10 can protrude from the exposed surface 11. As with FIG. 1E or 1E′, the dielectric layer 12 can be provided over the elements 3a, 3b in FIG. 2D. An upper portion of the dielectric layer 12 can be removed (for example, by polishing, grinding, etc.) to expose the vias 10 at the exposed upper portion 14 of the dielectric layer 12. As with the embodiment of FIGS. 1A-1G, once the vias 10 are exposed, a gap 7 may be provided between the elements 3a, 3b as shown in FIG. 2E.

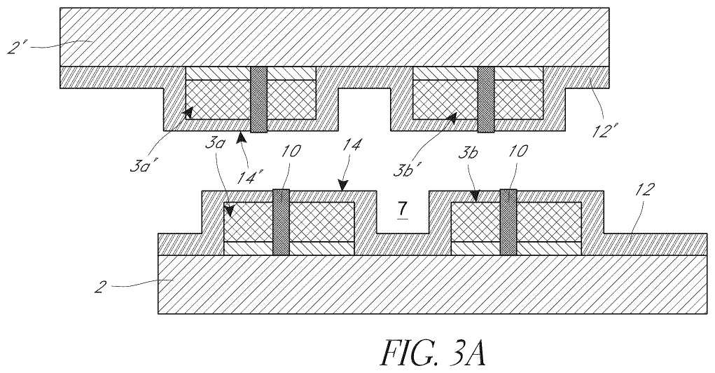

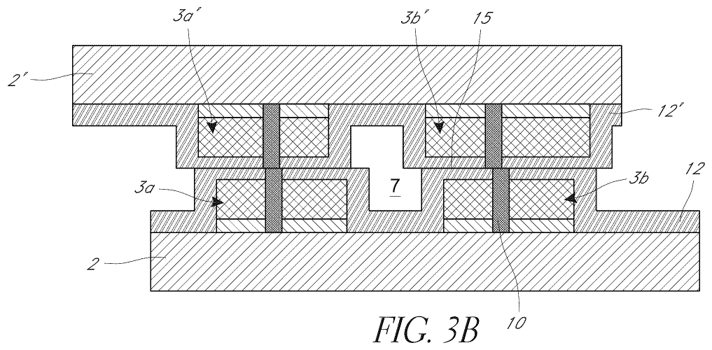

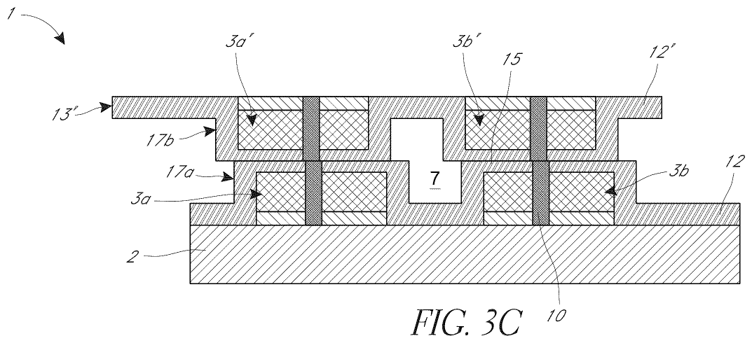

FIGS. 3A-3C illustrate various stages of a direct gang bonding process in which a first plurality of elements 3a, 3b is direct bonded to a corresponding second plurality of elements 3a′, 3b′ without intervening adhesives. In some embodiments, the bonding process illustrated in FIGS. 3A-3C can be used for a wafer to wafer bonding process, in which each wafer includes numerous elements to be directly bonded. Unless otherwise noted, components of FIGS. 3A-3C may be the same as or generally similar to like-numbered components of FIGS. 1A-2D. For example, in FIG. 3A, the exposed upper surfaces 14, 14′ of the dielectric layers 12, 12′ of the elements 3a, 3b, 3a′, 3b′ can be prepared for direct bonding as explained above in connection with FIG. 1A. In various embodiments, the processes described in connection with FIGS. 1G and 2E may be used to at least partially prepare the surfaces of the dielectric layer 12 for bonding. Additional processing may be performed to prepare the dielectric layer 12 and the contact pads connected to the exposed portion of the vias 10 for direct bonding. For example, in some embodiments, the surfaces 14, 14′ to be bonded may be very lightly etched for activation and exposed to a nitrogen-containing solution and terminated with a nitrogen-containing species. For example, oxygen reactive ion etching plasma and nitrogen radical activation may be used. As another example, the surfaces 14, 14′ to be bonded may be exposed to an ammonia dip after a very slight etch, and/or a nitrogen-containing plasma (with or without a separate etch). Further, in some embodiments, a pre-process for direct bonding may be performed. For example, the pre-process may include a surface cleaning process such as a vacuum ultraviolet irradiation, a vacuum ultraviolet/ozone irradiation, sulfuric-peroxide mixture (SPM) cleaning process, etc.

In FIG. 3B, the elements 3a′ and 3b′ may be simultaneously brought into direct contact with the elements 3a, 3b. For example, once the surfaces 14, 14′ are prepared, nonconductive field regions of the elements 3a, 3b can be brought into contact with each other. The interaction of the activated surfaces can cause the nonconductive regions of the elements 3a, 3b to directly bond with the corresponding nonconductive regions of the elements 3a, 3b without an intervening adhesive, without application of external pressure, without application of voltage, and about room temperature. In various embodiments, the bonding strength of the nonconductive regions can be covalent bonds that are greater than Van der Waals bonds. In some embodiments, covalent bonding can occur between the surfaces 14, 14′. The bonded structure 1 can be annealed after directly bonding the surfaces 14, 14′.

In some embodiments, the structure of FIG. 3B can be annealed at elevated temperature to enhance the bond strength of the non-conductive area around via 10 and to form direct metal-to-metal bonding of the vias 10 (or contact pads connected to the vias 10). Thus, in FIG. 3B, the element 3a′ can be directly bonded to the element 3a along a bond interface 15 without an intervening adhesive. The element 3b′ can be directly bonded to the element 3b along a bond interface 15 without an intervening adhesive. In some embodiments, the same or a generally similar method of directly bonding the elements 3a, 3b and the carrier 2 can be used for bonding the elements 3a′, 3b′ and the elements 3a, 3b, respectively.

As shown, prior to and during direct bonding of the elements 3a, 3a′, 3b, 3b′, the elements 3a, 3b (and also the elements 3a′, 3b′) may occlude the gap 7 in which no filling material is disposed. Rather, as shown in FIGS. 3A-3B, the gap 7 may be filled with a gas (such as air) or under vacuum. Beneficially, the absence of filling material during bonding can reduce stresses on the elements 3a, 3b that may be introduced during heating due to different coefficients of thermal expansion (CTE) of the filling material(s) and may reduce the number of process steps, thus lowering fabrication costs.

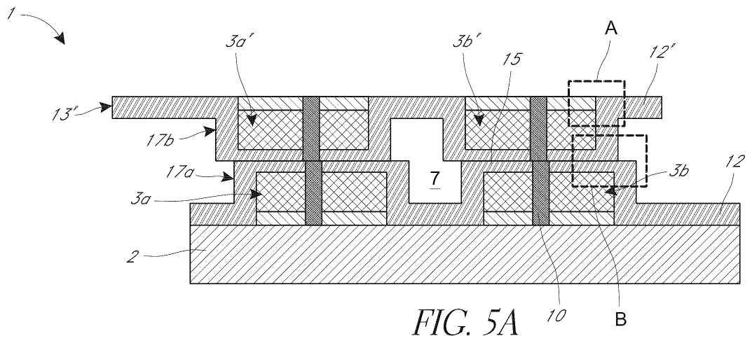

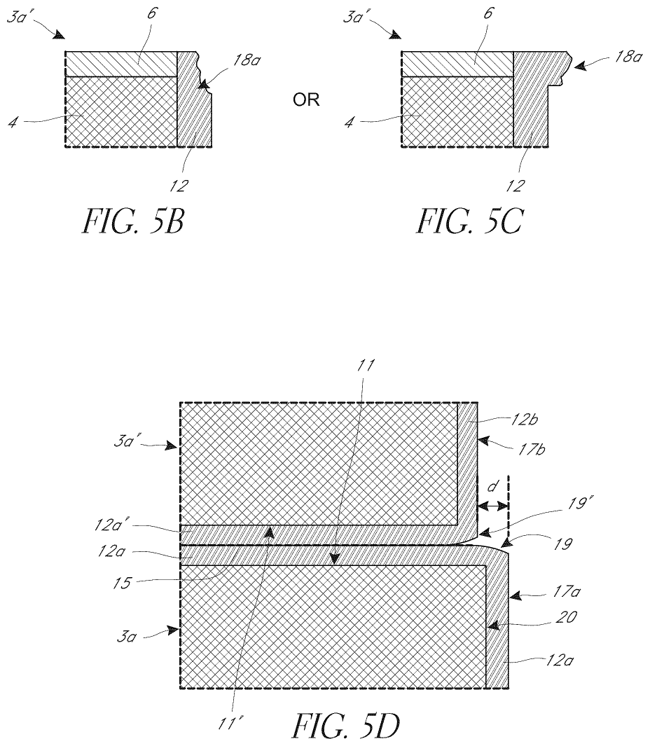

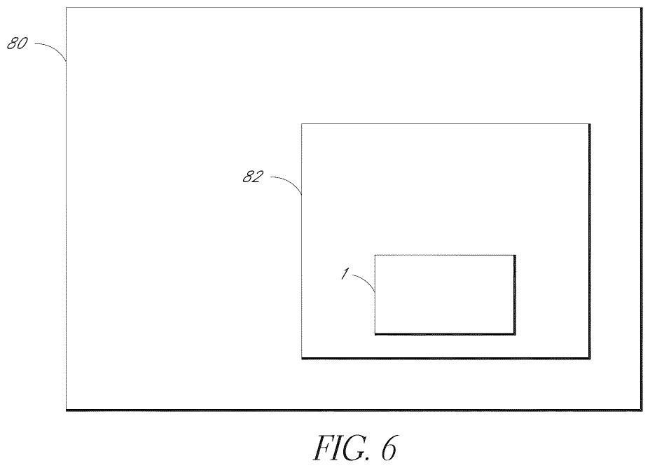

Turning to FIG. 3C, the carrier 2′ to which the elements 3a′, 3b′ are bonded may be removed. As shown in FIG. 3C, the elements 3a, 3a′ and 3b, 3b′ may be slightly laterally offset relative to one another, due to, for example, inaccuracies in the alignment process. The carrier 2′ can be removed in any suitable manner, for example, by etching, grinding, polishing, etc. In some embodiments, the carrier 2 to which the elements 3a, 3b are bonded may also be removed. As shown in FIG. 3C, the dielectric layer 12′ on the element 3a′ can define a first outer surface 17a, and the dielectric layer 12 on the element 3b can define a second outer surface 17b. In some embodiments, the bonded structure 1 of FIG. 3C can be integrated into the larger electronic system, for example, by mounting the bonded structure 1 to a system or motherboard. In some embodiments, therefore, the first and second outer surfaces 17a, 17b can be exposed on an exterior surface of the bonded structure 1. As shown in FIG. 3C, an overhanging portion 13′ of the dielectric layer 12′ can remain after the removal of the carrier 2′, and can overhang the bonded structure. As shown in FIGS. 5B-5C, the overhanging portion of the dielectric layer 12 may break off during subsequent processing.

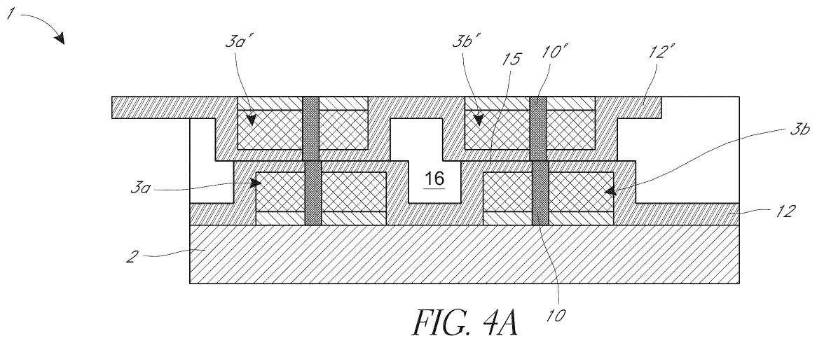

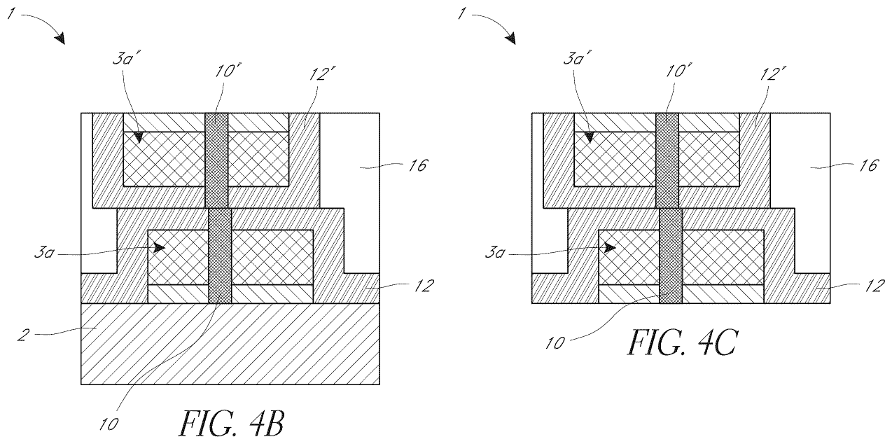

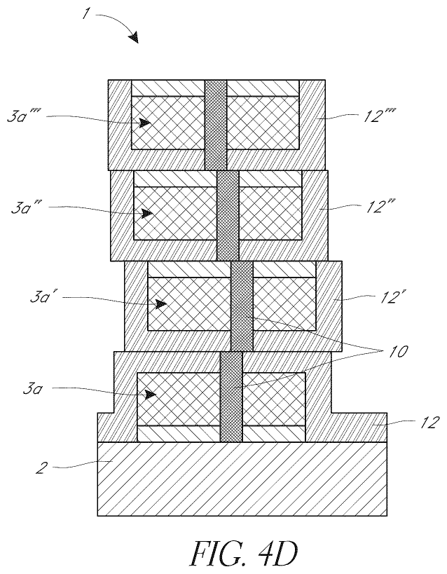

FIGS. 4A-4D illustrate examples of bonded structures 1 during various stages of a stacking process. Unless otherwise noted, components of FIGS. 4A-4D may be the same as or generally similar to like-numbered components of FIGS. 1A-3C. In some embodiments, the same or a generally similar method of directly bonding the elements 3a, 3b associated with FIGS. 1A-3C can be used. In FIG. 4A, for example, the gap 7 between the elements 3a, 3a′, 3b, 3b′ produced in FIG. 3C can be filled with a filling material 16, such as a molding compound. The filling material 16 can protect the elements 3a, 3a′, 3b, 3b′ during a subsequent process or during operation. The filling material 16 can be applied within the gaps disposed between adjacent stacked structures. For example, the filling material 16 can be applied in a flowable form, and can be hardened by/after curing. The filling material 16 can be applied after the elements 3a, 3a′ and the elements 3b, 3b′ are direct bonded, such that the filling material 16 can comprise a seamless filler. For example, the filling material 16 can comprise a single layer of filler. In other embodiments, however, no filling material can be applied, and the bonded structure 1 of FIG. 3C can be integrated into the larger electronic system.

As shown in FIG. 4B, the bonded structure 1 of FIG. 4A can be singulated along saw lines between the elements 3a, 3b and between the elements 3a′, 3b′ to form a singulated bonded structure 1. Thus, in the singlulated bonded structure 1 of FIG. 4B, the filling material 16 can be disposed along the side surfaces of the singlulated bonded structure 1. The filling material 16 can comprise markings indicative of a sawing process or other methods such as laser stealth dicing or laser ablation used during singulation. The carrier 2 may remain bonded to the elements 3a, 3b for integration into the larger electronic system or device in some embodiments. For example, the carrier 2 can be bonded (e.g., direct bonded or adhered with an adhesive such as solder) to a motherboard of the larger electronic system. In other embodiments, as shown in FIG. 4C, the carrier 2 can be removed such that the elements 3a, 3b and/or 3a′, 3b′ can be bonded to the motherboard of the larger electronic system.

FIG. 4D illustrates a bonded structure 1 in which more than two elements are bonded together to form a stacked bonded structure. For example, in FIG. 4D, element 3a″ can be directly bonded to element 3a′, and element 3a′″ can be directly bonded to element 3a″. The interconnects or vias 10 can provide vertical electrical communication among the elements 3a-3a′″. Although four elements 3a-3a.′ are shown in FIG. 4D, in other embodiments, more or fewer than four elements can be provided. In the embodiment of FIG. 4D, the outer side surfaces defined at least in part by the dielectric layers 12, 12′, 12″, 12′″ can be exposed on the exterior surface of the bonded structure 1. In other embodiments, as with FIGS. 4A-4C, a filling material can be provided between the bonded structures such that, in FIG. 4D, the filling material can be disposed alongside surfaces of the dielectric layers 12, 12′, 12″, 12′″.

FIG. 5A illustrates a bonded structure 1 prior to singulation. FIGS. 5B-5D illustrate magnified portions of the bonded structure 1 of FIG. 5A. Unless otherwise noted, components of FIGS. 5A-5D may be the same as or generally similar to like-numbered components of FIGS. 1A-4D. As explained above, in various embodiments, one or both carriers 2, 2′ can be removed from the bonded structure. For example, the carrier(s) 2 and/or 2′ can be removed by etching, grinding, polishing, or any other suitable removal method. When the carrier 2′ is separated from the dielectric layer 12′, a portion of the dielectric layer 12′ can fracture or break away from the carrier 2′. The breaking away of the carrier 2′ from the dielectric layer 12′ can form a fractured surface (or structure) 18a or 18b in the dielectric layer 12′. For example, as shown in FIG. 5B, in some cases, the fractured surface 18a can comprise a concave surface in which a portion of the dielectric material 12′ along side surfaces 20 of the element 3a′ is removed. In other cases, as shown in FIG. 5C, a fractured surface 18b can comprise a concave surface or projection that extends outwardly from the side of the bonded structure 1. As shown in FIGS. 5B and 5C, the fractured surface (or structure) 18a or 18b can be disposed at a portion of the dielectric layer 12′ at or near a surface of the element 3a′ opposite the bonding interface 15 between the elements 3a, 3a′. In some embodiments, when the carrier 2′ is separated from the dielectric layer 12′, an interface where the element 3a′ and the dielectric layer 12′ meet can fracture or break away from the carrier 2′ (not illustrated). Still in some embodiments portions dielectric layer 12′ abutting carrier 2′ may be selectively removed (not illustrated) prior to the bond of the horizontal surface of elements 3a and 3b to the respective counterparts 3a′ and 3b′. The selective removal of selected portions of dielectric layer 12′ from the surface of carrier 2′ reduces the incidence of fractures of FIGS. 5B and 5C during the removal of carrier 2′.

Turning to FIG. 5D, as explained above, the dielectric layers 12, 12′ can coat (e.g., conformally coat in some embodiments) side surfaces 20 of the elements 3a, 3a′ and the exposed upper surfaces 11, 11′ of the respective elements 3a, 3a′. For example, as shown in FIG. 5D, upper portions 12a′ of the dielectric layers 12′ can be provided over the exposed upper surfaces 11, 11′ of the respective elements 3a, 3a′. The upper portion 12a of the dielectric layer 12 on the element 3a can be directly bonded without an intervening adhesive to the corresponding upper portion 12a′ of the dielectric layer 12′ on the element 3a′. Further, as shown in FIG. 5D, the dielectric layers 12, 12′ can be rounded or curved along curved surfaces 19, 19′ that are disposed between the side surfaces 20, 20′ and the upper surfaces 11, 11′ of the elements 3a, 3a′. For example, the first dielectric layers 12, 12′ is curved along an edge or corner of the first and the second element 3a, 3a′ between the first and second bonding surfaces and the at least one first and second side surface. As explained above, the elements 3a, 3a′ may be slightly misaligned such that, after direct bonding, side surfaces 20, 20′ of the elements 3a, 3a′ and outer surfaces 17a, 17b of the dielectric layers 12, 12′ are laterally offset relative to one another by an offset distance d. The offset distance d can be less than 2 μm, less than 5 μm, or less than 10 μm, for example, in a range of 0.2 μm to 10 μm, in a range of 0.2 μm to 5 μm, in a range of 0.2 μm to 2 μm, or in a range of 0.2 μm to 1 μm. In various embodiments the offset distance d can be less than the width of the via 10 or other contact pads which are connected to one another (which as explained above can result from misalignment between the top and bottom elements or dies). In various embodiments, for example, the offset distance d can be substantially smaller than a width of the contact pads or vias 10. For example, the offset distance d can be less than 95% of the width of contact pads or vias 10, or less than 60% of the width of contact pads or vias 10. The offset distance d may be sufficiently small such that contact pads connected to the interconnects 10 maintain direct contact after bonding. In some embodiment, the offset distance d is less than 5% of the thickness of the elements 3a or 3b, for example, less than 10% of the thickness of the elements 3a, 3b.

FIG. 6 is a schematic diagram of a system 80 incorporating one or more bonded structures 1, according to various embodiments. The system 80 can comprise any suitable type of electronic device, such as a mobile electronic device (e.g., a smartphone, a tablet computing device, a laptop computer, etc.), a desktop computer, an automobile or components thereof, a stereo system, a medical device, a camera, or any other suitable type of system. In some embodiments, the electronic device can comprise a microprocessor, a graphics processor, an electronic recording device, or digital memory. The system 80 can include one or more device packages 82 which are mechanically and electrically connected to the system 80, e.g., by way of one or more motherboards. Each package 82 can comprise one or more bonded structures 1. The bonded structures 1 shown in FIG. 6 can comprise any of the bonded structures 1 shown and described above in connection with FIGS. 1A-5D. The bonded structure 1 can include one or more integrated device dies which perform various functions for the system 80.

For purposes of summarizing the disclosed embodiments and the advantages achieved over the prior art, certain objects and advantages have been described herein. Of course, it is to be understood that not necessarily all such objects or advantages may be achieved in accordance with any particular embodiment. Thus, for example, those skilled in the art will recognize that the disclosed implementations may be embodied or carried out in a manner that achieves or optimizes one advantage or group of advantages as taught or suggested herein without necessarily achieving other objects or advantages as may be taught or suggested herein.

All of these embodiments are intended to be within the scope of this disclosure. These and other embodiments will become readily apparent to those skilled in the art from the following detailed description of the embodiments having reference to the attached figures, the claims not being limited to any particular embodiment(s) disclosed. Although this certain embodiments and examples have been disclosed herein, it will be understood by those skilled in the art that the disclosed implementations extend beyond the specifically disclosed embodiments to other alternative embodiments and/or uses and obvious modifications and equivalents thereof. In addition, while several variations have been shown and described in detail, other modifications will be readily apparent to those of skill in the art based upon this disclosure. It is also contemplated that various combinations or sub-combinations of the specific features and aspects of the embodiments may be made and still fall within the scope. It should be understood that various features and aspects of the disclosed embodiments can be combined with, or substituted for, one another in order to form varying modes of the disclosed implementations. Thus, it is intended that the scope of the subject matter herein disclosed should not be limited by the particular disclosed embodiments described above, but should be determined only by a fair reading of the claims that follow.

What is claimed is:

1. A bonded structure comprising:
a first element having a first dielectric layer including a first bonding surface and at least one first side surface of the first element; and
a second element having a second dielectric layer including a second bonding surface and at least one second side surface of the second element, the second bonding surface of the second element directly bonded to the first bonding surface of the first element without an adhesive.

2. The bonded structure of claim 1, wherein the at least one first side surface of the first dielectric layer is laterally offset from the at least one second side surface of the second dielectric layer.

3. The bonded structure of claim 2, wherein an amount of the offset is less than 10% of a thickness of at least one of the bonded first or second element.

4. The bonded structure of claim 1, further comprising a single layer filler disposed along the first and second dielectric layers at least at the first and second side surfaces of the first and second elements.

5. The bonded structure of claim 4, wherein the single layer filler comprises a molding compound.

6. The bonded structure of claim 1, wherein the first side surface and the second side surface are exposed on an exterior surface of the bonded structure.

7. The bonded structure of claim 1, wherein the first dielectric layer and second dielectric layer are conformal.

8. The bonded structure of claim 1, wherein the first dielectric layer is curved along an edge of the first element between the first and second bonding surfaces and the at least one first and second side surface.

9. The bonded structure of claim 1, wherein a portion of the first dielectric layer or the first element comprises a fractured structure.

10. The bonded structure of claim 1, wherein a peripheral portion of the bonding surfaces of the first and second elements are not bonded.

11. The bonded structure of claim 1, further comprising a third element directly bonded to the second element without an adhesive.

12. The bonded structure of claim 1, wherein the first element comprises a first conductive contact pad directly contacting a second conductive contact pad of the second element.

13. The bonded structure of claim 12, further comprising a first conductive via extending through the first element and electrically connected to the first conductive contact pad, and a second conductive via extending through the second element and electrically connected to the second conductive contact pad.

14. A bonded structure comprising:
a first dielectric layer on a first element and on a third element, the first dielectric layer being formed on a bonding surface and a side surface of each of the first and the third elements;
a second dielectric layer on a second element and on a fourth element, the second dielectric layer being formed on a bonding surface and a side surface of each of the second and fourth elements;
wherein a first portion of the first dielectric layer is directly bonded to a first portion of the second dielectric layer to form a first bonded structure, and a second portion of the first dielectric layer is directly bonded to a second portion of the second dielectric layer to form a second bonded structure without an adhesive, wherein the first bonded structure is spaced from the second bonded structure by a gap.

15. The bonded structure of claim 14, further comprising a single layer filler disposed along the first and second dielectric layers at least at the first and second side surfaces of the first and second elements.

16. The bonded structure of claim 15, wherein the single layer filler comprises a molding compound.

17. A bonded structure comprising:
first and third singulated elements directly bonded to a first carrier without an intervening adhesive, at least the first singulated element comprising an integrated device die, wherein the first and third singulated elements are spaced apart by a gap;
second and fourth singulated elements directly bonded to a second carrier without an intervening adhesive;
wherein a first portion of a first dielectric layer disposed on the first singulated element is directly bonded to a first portion of a second dielectric layer disposed on the second element without an intervening adhesive; and
wherein a second portion of a first dielectric layer disposed on the first singulated element is directly bonded to a second portion of a second dielectric layer disposed on the second singulated element without an intervening adhesive.

18. The bonded structure of claim 17, wherein the first side surface and the second side surface are exposed on an exterior surface of the bonded structure.

19. The bonded structure of claim 17, wherein the first dielectric layer and second dielectric layer are conformal.

20. The bonded structure of claim 17, wherein a portion of the first dielectric layer or the first element comprises a fractured structure.
